(19) United States
(12) Patent Application Publication
(10) Pub. No.: US 2024/0210452 A1
(43) Pub. Date: Jun. 27, 2024

(54) ESTIMATION OF AN ELECTRICITY PRODUCTION FOR A SET OF PRODUCTION SITES BY INDIVIDUALLY OPTIMIZED NEURAL NETWORKS

(71) Applicant: ATOS WORLDGRID, Bezons (FR)

(72) Inventor: Rémi POUCHAIN, La Tronche (FR)

(73) Assignee: ATOS WORLDGRID, Bezons (FR)

(21) Appl. No.: 18/393,856

(22) Filed: Dec. 22, 2023

(30) Foreign Application Priority Data
Dec. 23, 2022 (EP) 22307033.5

(51) Int. Cl. G01R 21/133

(52) U.S. Cl. CPC G01R 21/133

(57) ABSTRACT

The invention relates to a method for estimating an electricity production of a set of production sites, comprising for each of said sites:
acquiring an optimized set of parameters relating to the site,
providing these parameters to a neural network associated with said site in order to obtain an estimated production
said estimation being determined based upon the productions estimated by each of said neural networks;
each of said neural networks being previously determined by:
training on a training set corresponding to the site associated with said neural network and based on an extended set of parameters relating to the site, and according to a loss function;
a first optimization phase consisting of selecting an optimized set of parameters among the extended set of parameters based upon the influence of the parameters on the training of said neural network;
a second optimization phase consisting of iteratively modifying at least one structural parameter of the neural network in order to select at least one optimal structural parameter, based upon the influence of this structural parameter on the training of said neural network.

### FIELD OF THE INVENTION

The present invention relates to the estimation of a power production over a geographical area. It applies particularly to the projected estimation of such a production when power production sites are dependent on external elements such as meteorological elements.

### Context of the Invention

In order to best manage the equilibrium between power production and consumption, it is important to be able to estimate future production as reliably as possible.

This equilibrium must be managed on the scale of a relevant geographical area, corresponding to the distribution network, for example a region or a country.

This geographical area may comprise a plurality of power production sites that can use varied technologies for power production. The production sites can especially be nuclear power plants, thermal power plants, solar power plants, wind farms, etc.

To estimate the power production in this area, the power produced by all of the production sites located in the area is generally estimated, by means of a generic model.

However, such an approach poses the problem of identifying the production site or sites that might cause a drop in production, for example due to an equipment failure. Further, due to the variety of types of power production, different phenomena can impact the production of the sites, especially meteorological phenomena, and this global approach does not make it possible to measure the differentiated impact of these phenomena on the different production sites.

It is therefore interesting to have an estimation of power production for each production site and not for the entire geographical area.

Different technologies are used to model the behavior of the production sites and thus to be able to predict a future production based upon known production parameters, internal to the production site or external (meteorological data, for example, which strongly influence production in the case of wind or solar sites).

It has been proposed especially to use random forest classifiers or LSTM (Long Short Term Memory) neural networks, which are capable of taking into account a temporal aspect in the input data.

Such an approach is for example presented in the article by Mahjoub, S.; Chrifi-Alaoui, L.; Marhic, B.; Delahoche, L. Predicting Energy Consumption Using LSTM, Multi-Layer GRU and Drop-GRU Neural Networks. Sensors 2022, 22, 4062. https://doi.org/10.3390/s22114062

However, in practice, such algorithms are very expensive in terms of computing and storage resources, especially during their training.

Indeed, a random forest classifier generates a decision tree that grows as the number of training data increases. Conversely, an LSTM neural network tests the relevance of each prior input data for the prediction, in order to identify the temporal links.

This cost is especially problematic when regular training is necessary. This is the case, for example, when a new production site is set up and offers few or no historical data on power production.

In practice, therefore, the training of the model is avoided, and a single, generic model is used for all the production sites. In other words, for each production site, the model will be applied to predict a future production and detect possible malfunctions and trends for this site in particular, but the prediction is based on a single, generic model.

Considering the specific features of each site, this results in reduced reliability of the predictions.

### SUMMARY OF THE INVENTION

The purpose of the present invention is to provide a method and a system at least partially overcoming the aforementioned drawbacks, and especially making it possible to improve the reliability of the production predictions for each production site of a given geographical area.

To this end, the present invention relates to a method for estimating an electricity production of a set of production sites, including for each of said sites:
acquiring an optimized set of parameters relating to said site,
providing said parameters to a neural network associated with said site in order to obtain an estimated production, said estimation being determined based upon the productions estimated by each of said neural networks;
each of said neural networks being previously determined by:
training on a training set corresponding to the site associated with said neural network and based on an extended set of parameters relating to said site, and according to a loss function;
a first optimization phase consisting of selecting an optimized set of parameters among said extended set of parameters based upon the influence of said parameters on the training of said neural network;
a second optimization phase consisting of iteratively modifying at least one structural parameter of said neural network in order to select at least one optimal structural parameter, based upon the influence of said at least one structural parameter on the training of said neural network.

According to preferred embodiments, the invention comprises one or more of the following features, which may be used separately or in partial combination with one another, or in full combination with one another:
said parameters comprise meteorological data corresponding to said site;
said neural networks are multilayer feedforward neural networks;
said first optimization phase comprises triggering discrete instances of training said neural network by replacing the values of at least one parameter of said training set with other values, and selecting said optimized set of parameters relating to said site, based upon the differences in the evolution of said loss function;
in said first optimization phase, each parameter of said extended set of parameters is tested iteratively;
said second optimization phase comprises triggering discrete instances of training said neural network, iteratively modifying a number of layers of said neural network in order to select at least one optimal number of layers, then iteratively modifying a number of neurons by layers in order to select an optimal number of neurons per layer;
between 3 and 10 optimal numbers of layers are selected;
said second optimization phase is based on a NEAT algorithm;
said production sites belong to an electrical network of a power production company.

Another object of the invention relates to a computer program comprising instructions which, when the program is executed by a computer, lead said computer to implement the method as previously described.

Another object of the invention relates to a device for estimating an electricity production of a set of production sites, including for each of said sites, means for
acquiring an optimized set of parameters relating to said site,
providing said parameters to a neural network associated with said site in order to obtain an estimated production,
said estimation being determined based upon the productions estimated by each of said neural networks;
each of said neural networks being previously determined by:
training on a training set corresponding to the site associated with said neural network and based on an extended set of parameters relating to said site, and according to a loss function;
a first optimization phase consisting of selecting an optimized set of parameters among said extended set of parameters based upon the influence of said parameters on the training of said neural network;
a second optimization phase consisting of iteratively modifying at least one structural parameter of said neural network in order to select at least one optimal structural parameter, based upon the influence of said at least one structural parameter on the training of said neural network.

Thus, the invention is based on the principle of models that are highly specific to each production site and created automatically, while the state of the art generally proposes the use of a single, generic model for all these sites.

According to the invention, the estimation of the productions of each site is based on an individually optimized neural network.

The reliability and scalability are thus greatly improved.

Other characteristics and benefits of the invention will become apparent upon reading the following description of a preferred embodiment of the invention, given as an example with reference to the attached drawings.

### BRIEF DESCRIPTION OF THE DRAWINGS

FIG. 1 schematically depicts the functional architecture for estimating a predicted production for a power production site.

FIG. 2 schematically depicts an example of a functional architecture for estimating a total production for a set of power production sites.

### DETAILED DESCRIPTION OF THE INVENTION

The invention applies particularly to the estimation of a total electricity production for a set of production sites, which may for example correspond to a geographical area. It may extend to the case of a singleton, that is to say, of a set reduced to a single site.

It applies especially to the situation wherein, for at least some of these sites, the electricity production cannot be determined deterministically by a mathematical or empirical rule. This is especially the case of sites on which production depends on external elements of which the evolution over time is not known. From the point of view of the system, these elements can be seen as erratic since they have no known causality.

Typically, these external elements may be meteorological elements. For example, the amount of wind (duration, force, etc.) greatly impacts the electricity production of a wind turbine site. Likewise, cloud cover and solar radiation greatly impact the production of a solar panel site.

These elements are captured in the form of parameters that can be determined by measurement instruments and form inputs of an estimation system.

The parameters are specific to the site, since they can have a highly local value. However, they may originate from a remote source. For example, a temperature can be measured highly locally, but other parameters can be provided by data providers, for example meteorological data providers (for example, Météo France for France, etc.).

FIG. 2 exemplifies a functional, simplified architecture for estimating a total electricity production ET of a set of electricity production sites S₁, S₂, . . . , Sₖ, k representing the number of sites considered. These sites can, for example, belong to a given geographical area, and/or be managed by a single entity (electricity production company or branch thereof, etc.).

This geographical area may be an area corresponding to an electrical network, for example that of a power production company.

For each site, an optimized set, P₁, P₂, Pₖ, respectively, of parameters relating to this site, is acquired.

The term “optimized” is understood to mean that, according to the invention, it is sought to consider only a minimum number of parameters making it possible to obtain a reliable estimation.

A larger number of parameters can be available for the site in question, but according to the invention a subset, referred to as “optimized set”, is considered, that is to say, acquired and then provided to a respective neural network.

These parameters may comprise, for example:
latent heat flow, FLLAT,
sensitive heat flow, FLSEN,
balance of long-wavelength radiation at the top of the atmosphere, FLTHERM
specific humidity, HU2m
low-level cloud cover, NEBBAS
mid-level cloud cover, NEBMOY
total amount of precipitation, PRECIP
temperature, T2M
geopotentials, Z700hPa, Z850hPa, etc.
aerosol optical depth, AOD
amount of airborne particles, DEPOT
collective potential energy, CAPE
wind gust speed, FF_RAF10m
wind speed, FF1000hPa, FF800hPa, FF850gPa, FF900hPa, FF925hPa, FF950hPa, etc.
zonal wind component, U100m, U10m
meridian wind component, V100m, V10m
vertical velocity, VV600hPa

These parameters correspond to those that are currently measured and made available by a data provider such as “Météo France”. The catalogs of available data are accessible from Météo France, especially via their website: https://donneespubliques.meteofrance.fr/

These different parameters are also explained in the scientific literature, such as especially in the thesis by Angelique Godart, “Les précipitations orographiques organisées en bandes dans la région Cévennes-Vivarais. Caractérisation et contribution au régime pluviométrique”. Ocean, Atmosphere. Joseph Fourier University (Grenoble I), 2009, HAL Id: tel-00431254.

Other parameters may be available from other providers or measured locally on the production site.

Some parameters can also be calculated, that is to say, not the result, or not only the result, of measurements.

For example, modules for calculating the position of the sun and the moon can provide these parameters that may be useful for certain types of electrical power production (tidal power plants, etc.).

Modules can also calculate radiation data such as direct irradiation for normal incidence (DNI) or global horizontal irradiance (GHI).

The invention is independent, in its principle, of all the available parameters. It finds an additional advantage when a large number of parameters is available, by its mechanism for optimizing parameters taken into account for the prediction of a production estimation.

The optimized set is therefore a subset of that of the available parameters. This optimized set, P₁, P₂, Pₖ may be different (and is generally different) from one site to another, that is to say, consisting of different parameters among the available parameters. Of course, the values of these parameters can also be different (for a single parameter), since the local values are considered.

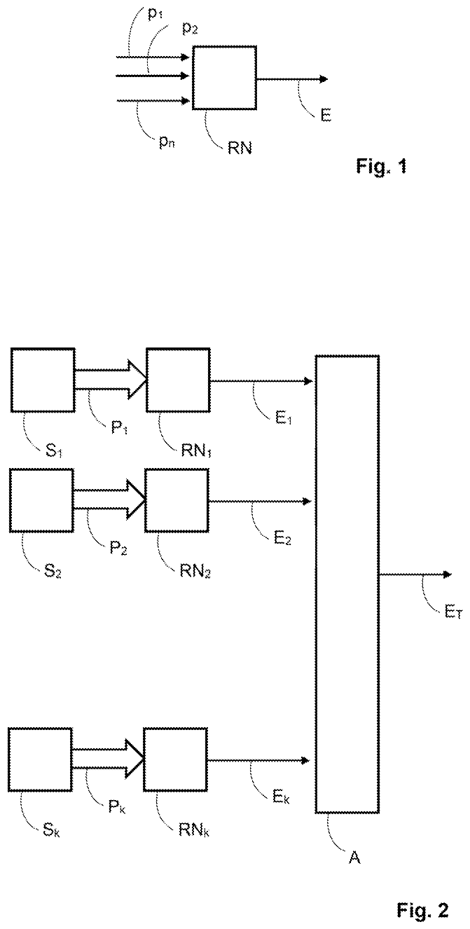

FIG. 1 depicts a system for estimating an electricity production for a single site.

The optimized set of parameters comprises n parameters, p₁, p₂, . . . , pₙ. These n parameters are provided to a neural network NN.

This neural network NN forms a predictive model, that is to say that it is adapted to make it possible, after training on a training set, to provide an estimation E of an electricity production from a vector formed by the values of the different parameters submitted as input p₁, p₂, . . . , pₙ.

According to one embodiment of the invention, the neural network NN can be based on a simple architecture.

In particular, according to one embodiment of the invention, the neural network NN can be a multilayer feedforward neural network. This type of network has the double advantage of speed for training and prediction, and of being architecturally simple and therefore well suited to the phases of optimizing at least one of its structural parameters, which will be described later.

It may especially be based on an initial architecture comprising a reduced number of layers and a reduced number of neurons per layer.

According to one embodiment of the invention, the values of the parameters are pre-processed before being provided as input to the neural network NN.

This pre-processing can be seen as a cleaning of the data, that is to say, a conversion between the values expressed in a format specific to the measurement instruments or to the data provider into a format corresponding to their utilization by the neural network NN.

This pre-processing comprises the deletion of incoherent data, that is to say, data that are outside a range of possible or plausible values, for the parameter considered. Some values may be technically impossible and therefore reflect a clear measurement error, and must therefore be ruled out. Others can be technically possible but are statistically aberrant and can also be considered as measurement errors and ruled out.

For example, a value reflecting a power production, at night, for a solar panel can be considered an error and ruled out. Likewise, a value exceeding the maximum theoretical production of a wind turbine may occur in the event of a wind gust, but should also be ruled out.

The pre-processing may also comprise the formatting of data. For example, times can be converted from a 12-hour format to a 24-hour format. Indeed, providing logical continuity for the daytime hours is more consistent for the neural network NN and makes it possible to improve the inclusion of such a parameter in learning and, consequently, in prediction.

The pre-processing may also comprise the enrichment of the parameters.

According to the invention, all or some of the parameters available for a given production site are provided to a neural network NN associated with this site. Extended set of parameters refers to all the parameters provided to the neural network NN.

The mechanisms explained in relation to FIG. 1 are effectively carried out for each production site considered S₁, S₂, . . . , Sₖ, as depicted in the example of FIG. 2.

As mentioned previously, the neural networks NN₁, NN₂, . . . , NNₖ can be based on the same initial architecture but may correspond to a different predictive model specific to the associated production site. This differentiation of the neural networks is achieved by a learning (or training) phase.

It will be recalled that, according to one embodiment of the invention, the neural network is based on a simple architecture (for example, multilayer feedforward neural networks with reduced numbers of layers and neurons per layer).

This training phase comprises training each neural network NN₁, NN₂, . . . , NNₖ based on the corresponding extended set of parameters and a loss function.

Each site has different parameters and parameter values. Also, each neural network NN₁, NN₂, . . . , NNₖ undergoes its own learning. Each neural network NN₁, NN₂, . . . , NNₖ thus forms a predictive model specific to the production site, defined by its internal parameters. These internal parameters comprise the synaptic weights of the neural network NN₁, NN₂, . . . , NNₖ but also structural parameters (number of layers, number of neurons per layer, etc.).

The loss function may, for example, be the normalized root mean square error or the normalized mean error, between the neural network output and the desired output.

The learning set therefore conventionally associates a vector formed of values of the input parameters with a desired output, typically referred to as tag.

This learning set may consist of the historical data of each site. In the absence of available historical data (in the case of a new site, for example), a history of another site of the same type and/or of a nearby region may be used.

According to the invention, the training (or learning) phase further comprises optimization phases.

A first optimization phase consists of selecting an optimized set of parameters among the extended set of parameters, for each site considered.

This selection is carried out based upon the influence of the parameters on the training of the neural network NN₁, NN₂, . . . , NNₖ.

The first training phase based on the extended set of parameters can provide a starting base, from which various subsets can be tested in order to obtain an optimized set that makes it possible both to reduce the number of parameters to be considered and to obtain good predictive characteristics of the neural network NN₁, NN₂, . . . , NNₖ.

In other words, it involves removing the parameters that have little influence on the predictions performed by the neural network NN₁, NN₂, . . . , NNₖ.

The percentage of influence of a parameter can, for example, be estimated by comparing the result of the loss function for the extended set of parameters and for this same set by replacing the values of this parameter with other values, in all or part of the training set. These other values may, for example, be random values.

It is then possible to compare the evolution of the loss function, for example by looking at the result thereof when the training set was submitted to the neural network NN₁, NN₂, . . . , NNₖ.

If the result is not substantially different, it means that this parameter has little influence and can be deleted.

In order to form an optimized set of parameters, all the parameters that have an influence lower than a certain threshold, that is to say that do not modify the result of the loss function beyond this threshold, can be deleted in this way. By way of example, the threshold may be 0.1%.

According to one embodiment of the invention, this phase can be implemented by iteratively testing each parameter of the extended set of parameters. A decision is taken for each parameter so as to form as output the optimized set of parameters.

According to one embodiment of the invention, this optimization phase is performed automatically and repeatedly over time. Indeed, it is noted that certain parameters have a correlation with the time of the year and/or the meteorology, so that the influence of some parameters may be greater or lesser over time. Updating the optimized set of parameters therefore makes it possible to further improve the performance of the predictive mechanism for estimating an electricity production.

A second optimization phase consists of iteratively modifying at least one structural parameter of the neural network NN₁, NN₂, . . . , NNₖ, in order to select at least one optimal structural parameter, based upon the influence of this structural parameter on the training of the neural network.

It will be recalled that the structural parameters of a neural network especially comprise a number of layers, a number of neurons per layer, etc.

According to the invention, therefore, the structure of each neural network NN₁, NN₂, . . . NNₖ may differ for each production site S₁, S₂, . . . , Sₖ.

According to one embodiment of the invention, this second optimization phase is based on the NEAT (NeuroEvolution of Augmented Topologies) algorithm.

This algorithm was presented in the article “Efficient Evolution of Neural Network Topologies” by Kenneth O. Stanley and Risto Miikkulainen, in Proceedings of the 2002 Congress on Evolutionary Communication (CEC'02), IEEE.

It is based on a genetic algorithm principle wherein the generation of new structures to be tested is carried out by random mutation from a previously tested structure, and by combining different previously tested structures. At each iteration, a selection step may only keep the interesting structures (that is to say, the ones that provide an efficiency greater than a given threshold).

According to one embodiment of the invention, this second optimization phase comprises, for each production site:
iteratively modifying a number of layers of the neural network in order to select an optimal number of layers, then,
iteratively modifying a number of neurons per layer in order to select an optimal number of neurons per layer.

The two steps can be carried out with the second following the first.

In the first step, the algorithm acts on the number of layers from the simple model that has been previously trained. As explained above, this model can be a multilayer neural network (or perceptron).

The algorithm proposes a given number of models referred to as “patiences”, for example between 3 and 10. These models correspond to a set of structural parameters defining the neural network, that is to say, herein, a number of layers. This number can be reduced or increased with respect to the initial network.

Each proposed neural network is trained from the learning set and then evaluated via the loss function.

In the second step, the same principle is applied for the number of neurons for each layer (the number of layers then being fixed during this step).

Thus, each proposed neural network is trained from the learning set and then evaluated via the loss function.

As long as the performance gain is greater than a threshold, it is iterated taking as basic structure the one that obtained the best performance in the preceding iteration.

The iterative process stops when no new structure can be proposed that substantially improves the performance (that is to say, above a given gain threshold). The structural parameters corresponding to the neural network that has the best performance are then selected.

The same optimization process is carried out for each site,

At the end of the learning phase, each site is thus associated with a discrete neural network both by the structural parameters and by the synaptic weights that have been trained on the basis of discrete learning sets, and on optimized sets of parameters that are also discrete.

The prediction phase consists of presenting, to each neural network, a vector of parameters (belonging to the corresponding optimized set) not belonging to the learning set and of obtaining estimated productions E₁, E₂, . . . , Eₖ at the output of these neural networks, NN₁, NN₂, . . . , NNₖ, respectively.

The estimation of total electricity production ET for the area can then be estimated by computing means A as a function of the productions estimated by each of the neural networks NN₁, NN₂, . . . , NNₖ, each corresponding to a given site of the area in question.

This estimation of total electricity production ET may be the sum of the productions estimated for each site, E₁, E₂, . . . , Eₖ.

Naturally, this invention is not limited to the examples and embodiments described and shown, but rather is subject to numerous variations accessible to the person skilled in the art.

What is claimed is:

1. A computer-implemented method for estimating (ET) an electricity production of a set of production sites (S1, S2, . . . , Sk), comprising for each of said sites:
acquiring an optimized set (P1, P2, . . . Pk) of parameters relating to said site;
providing parameters of said optimized set of parameters to a neural network (NN1, NN2, . . . , NNk) associated with said site in order to obtain an estimated production (E1, E2, . . . , Ek);
said estimation (ET) being determined based upon the productions estimated (E1, E2, . . . Ek) by each of said neural networks (NN1, NN2, . . . , NNk);
each of said neural networks (NN1, NN2, . . . , NNk) being previously determined during a training phase including:
training on a training set corresponding to the site associated with said neural network (NN1, NN2, . . . , NNk) and based on an extended set of parameters relating to said site, and according to a loss function;
a first optimization phase consisting of selecting the optimized set of parameters from said extended set of parameters based upon influence of the parameters of said extended set of parameters on the training of said neural network (NN1, NN2, . . . NNk);
a second optimization phase consisting of iteratively modifying at least one structural parameter of said neural network (NN1, NN2, . . . , NNk) in order to select at least one optimal structural parameter, based upon influence of said at least one structural parameter on the training of said neural network (NN1, NN2, . . . , NNk).

2. The method according to claim 1, wherein said parameters comprise meteorological data corresponding to said site.

3. The method according to claim 1, wherein said neural networks (NN1, NN2, . . . , NNk) are multilayer feedforward neural networks.

4. The method according to claim 1, wherein said first optimization phase comprises triggering discrete instances of training said neural network (NN1, NN2, . . . , NNk) by replacing values of at least one parameter of said training set with other values, and selecting said optimized set of parameters relating to said site, based on differences in the evolution of said loss function.

5. The method according to claim 1, wherein, in said first optimization phase, each parameter of said extended set of parameters is tested iteratively.

6. The method according to claim 1, wherein said second optimization phase comprises triggering discrete instances of training said neural network (NN1, NN2, . . . , NNk), by iteratively modifying a number of layers of said neural network (NN1, NN2, . . . , NNk) in order to select at least one optimal number of layers, then iteratively modifying a number of neurons per layer in order to select an optimal number of neurons per layer.

7. The method according to claim 6, wherein between 3 and 10 optimal numbers of layers are selected.

8. The method according to claim 6, wherein said second optimization phase is based on a NEAT algorithm.

9. The method according to claim 1, wherein said production sites belong to an electrical network of a power production company.

10. A computer program product comprising instructions which, when the program is executed by a computer, lead said computer to implement the steps of the method according to claim 1.

11. A device for estimating (ET) an electricity production of a set of production sites (S1, S2, . . . , Sk), comprising for each of said sites, means for:
acquiring an optimized set (P1, P2, . . . Pk) of parameters relating to said site,
providing parameters of said optimized set of parameters to a neural network (NN1, NN2, . . . , NNk) associated with said site in order to obtain an estimated production (E1, E2, . . . , Ek),
said estimation (ET) being determined based upon the productions estimated (E1, E2, . . . , Ek) by each of said neural networks (NN1, NN2, . . . , NNk);
each of said neural networks (NN1, NN2, . . . , NNk) being previously determined during a training phase including:
training on a training set corresponding to the site associated with said neural network (NN1, NN2, . . . , NNk) and based on an extended set of parameters relating to said site, and according to a loss function;
a first optimization phase consisting of selecting the optimized set of parameters from said extended set of parameters based upon influence of the parameters of said extended set of parameters on the training of said neural network (NN1, NN2, . . . NNk);
a second optimization phase consisting of iteratively modifying at least one structural parameter of said neural network (NN1, NN2, . . . , NNk) in order to select at least one optimal structural parameter, based upon influence of said at least one structural parameter on the training of said neural network (NN1, NN2, . . . , NNk).
